(19) United States
(12) Patent Application Publication
(10) Pub. No.: US 2013/0130419 A1
(43) Pub. Date: May 23, 2013

(54) NIGHT VISION IMAGING SYSTEM (NVIS) COMPATIBLE LIGHT EMITTING DIODE

(71) Applicants: Benjamin George PHIPPS, Long Beach, CA (US); Eric LEMAY, Laguna Niguel, CA (US)

(72) Inventors: Benjamin George PHIPPS, Long Beach, CA (US); Eric LEMAY, Laguna Niguel, CA (US)

(73) Assignee: Wamco, Inc., Fountain Valley, CA (US)

(21) Appl. No.: 13/738,327

(22) Filed: Jan. 10, 2013

Related U.S. Application Data
(62) Division of application No. 13/087,443, filed on Apr. 15, 2011.
(60) Provisional application No. 61/342,773, filed on Apr. 20, 2010.

(51) Int. Cl. H01L 33/50

(52) U.S. Cl. CPC H01L 33/502
USPC 438/27

(57) ABSTRACT

The present disclosure is directed to a LED assembly that is compatible for use with a night vision imaging system, Such LEDs may emit energy between 400 and 600 nm of the electromagnetic spectrum while limiting energy emissions between 600 and 1200 nanometers. Near infrared photochemistry is incorporated directly into the lens or encapsulant of an LED with an opaque package that limits transmission of visible and near infrared energy.

### CROSS-REFERENCE TO RELATED APPLICATIONS

This application is a divisional of U.S. patent application Ser. No. 13/087,443, filed on Apr. 15, 2011, entitled NIGHT VISION IMAGING SYSTEM (NVIS) COMPATIBLE LIGHT EMITTING DIODE, which claims the benefit of U.S. Provisional Application Ser. No. 61/342,773, filed on Apr. 20, 2010, entitled: NVIS COMPATIBLE LED. The prior applications are herein incorporated in their entirety by reference.

### STATEMENT REGARDING FEDERALLY SPONSORED RESEARCH OR DEVELOPMENT

Not applicable.

### REFERENCE TO A COMPACT DISK APPENDIX

Not applicable.

### BACKGROUND OF THE INVENTION

1. Field of the Invention

This invention relates to night vision imaging systems (NVIS), and particularly light emitting diodes (LEDs) for use with night vision imaging systems.

2. Description of Related Art

Pilot-aircraft interface is a major component of aerospace design. A pilot must be able to quickly determine flight critical information such as, but not limited to, location, altitude, engine status, and fuel level. This is especially true for pilots flying military aircraft which not only face extreme conditions but that have additional situational awareness requirements that require the pilot's attention. Such requirements include, but are not limited to, weapon systems management and safety concerns relating to the constant awareness of other aircraft.

Moreover, military aircraft must also be able to operate at night and under extreme conditions. Military pilots often fly at night using “near infrared” sensitive “night vision” goggles which allows them to fly at night while maintaining vision sensitivity. However, traditional instrumentation in an aircraft cockpit causes near infrared sensitive goggles to “bloom,” greatly reducing their effectiveness. As a result of the blooming effect, cockpit instrumentation lighting is filtered.

Aircraft instrumentation traditionally used incandescent filament lighting. Cathode ray tube (CRT) displays have also been used to provide information to the pilot. However, aircraft are increasingly using light emitting diodes (LEDs) and active matrix liquid crystal displays (AMLCDs) to provide that functionality. LEDs, with their low weight, low power consumption, stability to shock and vibration, long life, and reliability are becoming the ideal source for cockpit illumination. Filters are often used to prevent goggle bloom, but they tend to be bulky and expensive and introduce risk of infrared light leaking out and distorting the pilot's vision when using a night vision imaging system. What is needed is an LED package that can control its light emissions in order to function properly with a night vision imaging system without the use of a separate filter.

### BRIEF SUMMARY OF THE INVENTION

The present disclosure is directed to light emitting diodes (LEDs) that emit energy in the visible region of the electromagnetic spectrum while limiting emissions in the near infrared region of the electromagnetic spectrum. “Near infrared” is a term well-known in the art and generally refers to infrared light having wavelengths close to those of visible light. Specifically, it relates to the shorter wavelengths of radiation in the infrared spectrum and especially to those between 0.7 and 2.5 micrometers. The present disclosure is also directed to inorganic and/or organic dyes and pigments that are capable of suppressing near infrared light emissions. These additives are incorporated directly into an LED assembly. The disclosure herein provides for the creation of LED assemblies that do not require additional filtering and have little to no risk of infrared light leakage, while still conforming with industry and government standards. LEDs produced in accordance with the present disclosure are compatible with pick and place soldering equipment and are designed for a solder reflow process as known in the art.

In at least one embodiment of the present disclosure, the LED lens is designed to emit a maximum light output at 60 degrees from normal. This broad light distribution allows for a simplified “paint balancing processes” during the manufacturing of illuminated keyboards and panels.

### BRIEF DESCRIPTION OF THE SEVERAL VIEWS OF THE DRAWINGS

The foregoing summary, as well as the following detailed description, will be better understood when read in conjunction with the appended drawings. For the purpose of illustration, there is shown in the drawings certain embodiments of the present disclosure, it should be understood, however, that the invention is not limited to the precise arrangements and instrumentalities shown.

In the drawings:

FIG. 1 illustrates an embodiment with a resin encapsulant containing near infrared absorbers and visible color correcting dyes or pigments;

FIG. 2 illustrates an embodiment with a high temperature thermoplastic lens containing near infrared absorbers and visible color correcting dyes or pigments;

FIG. 3 illustrates a basic liquid dispensing system for potting or encapsulating LEDs in accordance with one embodiment;

FIG. 4 is a graph of the emission spectrum in accordance with an exemplary embodiment;

FIG. 5 is a graph of the emission spectrum in accordance with an exemplary embodiment; and

FIG. 6 is a graph of the emission spectrum in accordance with an exemplary embodiment of the present invention,

### DETAILED DESCRIPTION OF THE INVENTION

The present disclosure will now be described more fully with reference to the Figures in which various embodiments of the present invention are shown. The subject matter of the disclosure may, however, be embodied in many different forms and should not be construed as limited to the exemplary embodiments set forth herein.

The present disclosure is directed to light emitting diodes (LED) compatible with night vision equipment. In at least one embodiment, inorganic near infrared suppressing dyes and/or pigments are incorporated directly into a lens or encapsulant of a LED. In some embodiments, organic near infrared suppressing dyes and/or pigments are incorporated directly into a lens or encapsulant of a LED. In at least one embodiment, both organic and inorganic near infrared suppressing dyes and/or pigments are incorporated directly into a lens or encapsulant of a LED. In at least one embodiment, visible dyes or pigments are added to control the chromaticity of the LED. in at least one embodiment, the LED emits energy between 400 and 600 nanometers (nm) of the electromagnetic spectrum while limiting energy emission between 650 and 1200 nm.

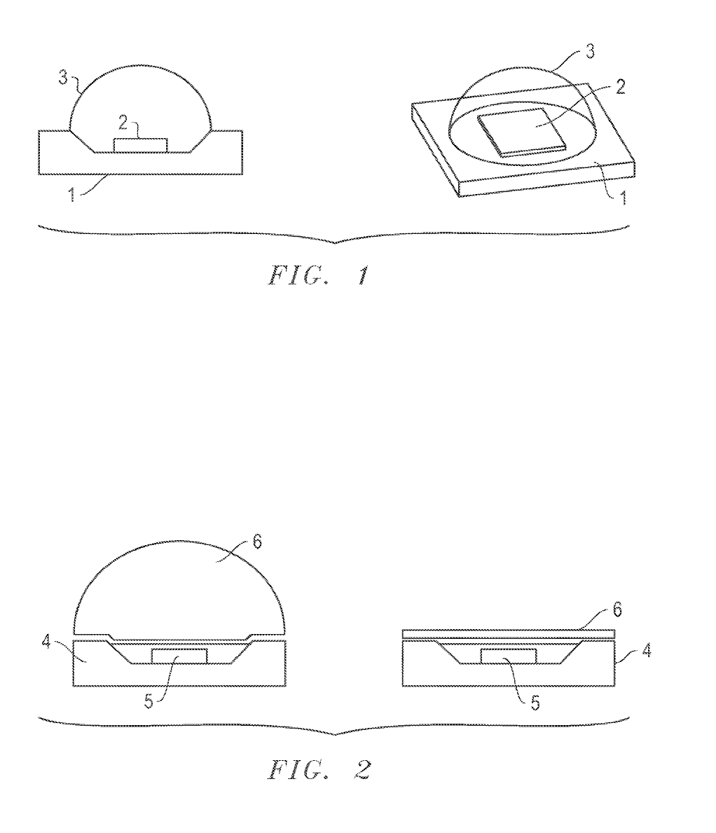

FIG. 1 shows an example of an LED with a resin encapsulant containing near infrared absorbers and visible color correcting dyes/pigments in accordance with the present disclosure. As shown in FIG. 1, the LED consists of an opaque package 1, a light emitting die 2, and a resin encapsulant 3 containing near infrared absorbers, light stabilizers, and visible color correcting dyes or pigments. In some embodiments, an opaque package 1 is defined as a package that emits less than 1% of the total output. In some embodiments, the light emitting die 2 is created by combining a phosphor with a blue LED. The light emitting die 2 can be created by any of the suitable manufacturing techniques known in the art, using materials such as Indium gallium nitride, Zinc selenide, Gallium(III) phosphide, Aluminum gallium indium phosphide, Gallium arsenide phosphide or any suitable material known in the art.

The resin encapsulant 3 is produced by combining a near infrared absorbing dye or pigment with a resin host. The resin host can be any of any optically transparent polymers known in the art such as, but not limited to, transparent polyester, polyurethane, polyepoxide, poly(methyl methacrylate) (PMMA), or silicone. The resin encapsulant 3 may be cured using any method known in the art, such as thermal or ultraviolet (UV) curing.

The dye or pigment may be an organic or inorganic infrared absorber. In some embodiments, the infrared absorber exhibits high absorbance in the red and near infrared regions of the electromagnetic spectrum. In one at least embodiment, the infrared absorbers preferably have an absorption peak between 650 nm and 1200 nm and limited absorption between 400 and 600 nm of the electromagnetic spectrum. While the near infrared absorbers may be any suitable absorber known in the art, the absorbers are preferably a metal dithiolene, a rylene, a porphyrin, a phthalocyanine, a naphthalocyanine, or some combination thereof. Phthalocyanines and naphthalocyanines are particularly well-suited for use because of their stability at high temperatures. The infrared absorber is preferably purified to substantially 99 percent using any suitable technique known in the art, such as, but not limited to, recrystallisation or column chromatography. Failure to properly purify the infrared absorber may inhibit the curing of the resin encapsulant 3 and/or reduce the thermal stability of the LED. This may result in a loss of absorbance and/or a yellow color shift over the operating life of the LED.

In one embodiment, an LED is created by incorporating the near infrared absorbers, any visible dyes/pigments, and LTV stabilizers, if necessary, into the resin host. In some embodiments, this incorporation may be done by creating a suspension using mixing or homogenization at elevated temperatures such as, but not limited to, temperatures in the range of 80 to 140 degrees Celsius. After cooling to room temperature, the suspension may then be mixed with the resin catalyst. In at least one embodiment, the mixture should be flooded with nitrogen at all times to limit exposure to moisture. The mixture is then degassed for 30 minutes or more at 29 inches mercury (inHg). The mixture may then be used in a resin dispensing machine (as described below) to create the LED.

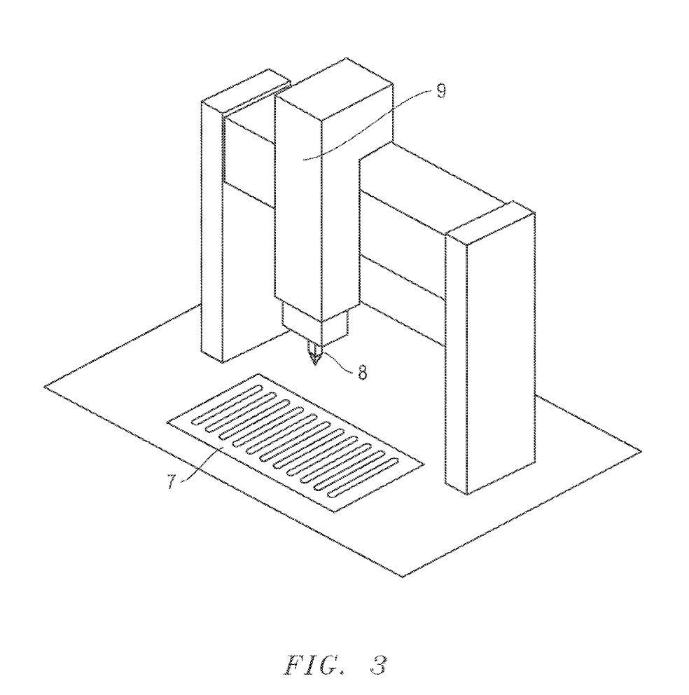

FIG. 3 provides an illustration, according to the present disclosure, of a resin dispensing machine. The machine includes a die and package holding plate 7, a dispensing nozzle 8, and a storage well or cartridge 9. A preset amount of resin is dispensed or molded onto an emitting die with an optically opaque package. The spectral distribution of the LED may be adjusted by altering the size and shape of the encapsulating lens.

In one embodiment, the near infrared absorbers may be incorporated into a high temperature molding or thermoforming resin, such as optically transparent polysulphone, PET, ultem, copolymers, or polycarbonate. FIG. 2 illustrates an example of such an embodiment. As shown in FIG. 2, such an embodiment includes an opaque package 4, an emitting die 5, and a polymeric lens 6 containing near infrared absorbers, light stabilizers, and/or visible correcting dyes or pigments. The emitting die 5 may be created by any known method in the art for combining a phosphor with a blue LED. The emitting die S may be created using any suitable manufacturing technique known in the art using any suitable emitting materials for creating green, yellow, blue, orange, red, or white LEDs. The material used may be any known in the art, including, for example, Indium gallium nitride, Zinc selenide, Gallium(III) phosphide, Aluminum gallium indium phosphide, Gallium arsenide phosphide.

The infrared absorbers are then mixed and incorporated into the high temperature molding or thermoforming resin using any method known in the art, including, for example, extrusion and injection molding practices. While the near infrared absorber may be any suitable absorber known in the art, in the preferred embodiment, the absorber is preferably a metal dithiolene, a rylene, a porphyrin, a phthalocyanine, a naphthalocyanine, or some combination thereof. The emitting die 5 should be packaged in such a way that it does not emit visible or near infrared light through the opaque package 4 of the LED.

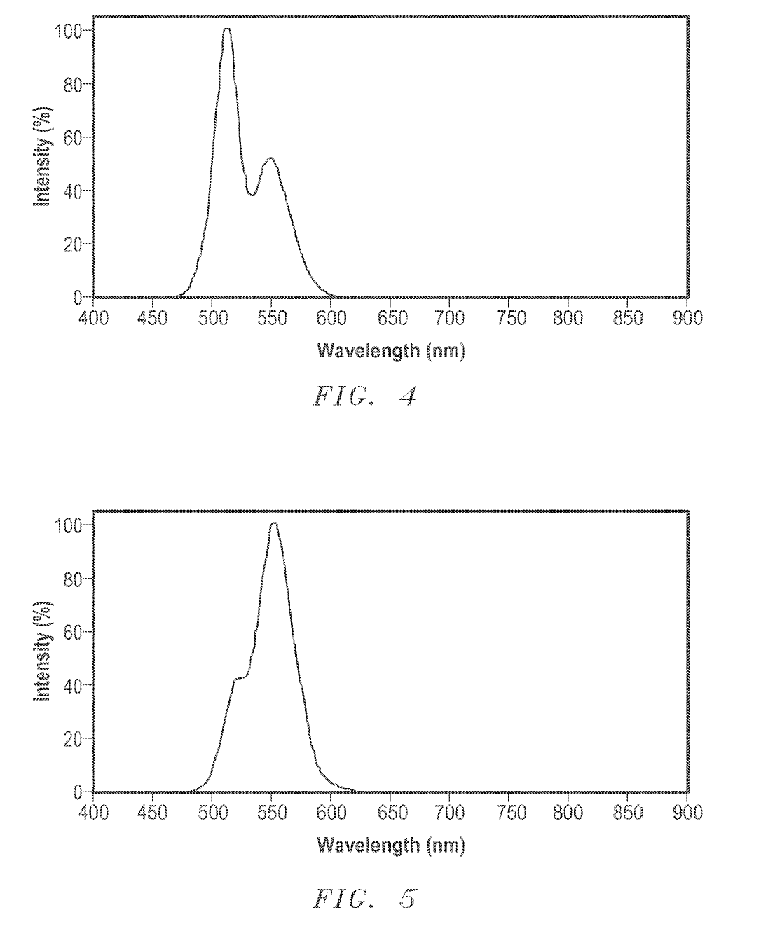

In one exemplary embodiment, near infrared absorbers, a UV stabilizer, visible color correction dyes, and a nickel quencher are added to a two component polyepoxide. The green colored mix is then molded onto an opaque package and cured at 80 degrees Centigrade (C) for three hours. When finished, such an embodiment will have color coordinates on the CIELUV uniform chromaticity diagram (also known as the CIE 1976 UCS) approximately U′=0.082 and V′=0.570 with a light output of 200 milli-candela (mcd) and emit a maximum light output 60 degrees from normal. A graph of the emission spectrum of such an embodiment is provided as FIG. 4.

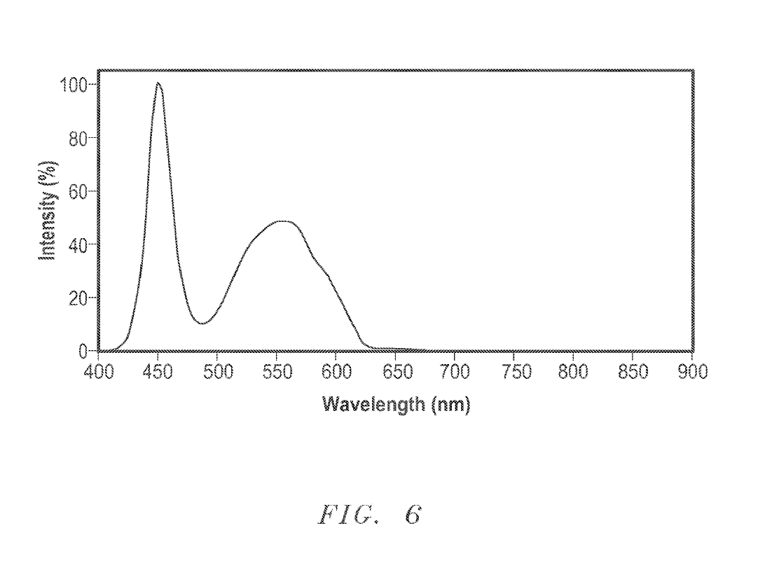

Different embodiments may be formed in a similar manner having different characteristics depending upon need, performance, or some other criteria such as military and/or government regulations. For example, another exemplary embodiment formed in a similar manner may have CIE 1976 UCS color coordinates approximately U′=0.127 and V′=0.577 with a light output of 150 mcd and emit a maximum light output 60 degrees from normal. A graph of the emission spectrum of such an exemplary embodiment is provided as FIG. 5.

In one embodiment, near infrared absorbers are incorporated into a high temperature thermoplastic resin. The near infrared absorbers and color correcting dyes/pigments are then molded into a high temperature polycarbonate copolymer and bonded to an LED. When finished, such an embodiment will have CIE 1976 UCS color coordinates approximately U′=0.171 and V′=0.456 with a light output of 150 mcd. A graph of the emission spectrum of such an embodiment is provided as FIG. 6.

In one embodiment, an LED assembly finished according the present disclosure will have CIF 1976 UCS color coordinates of approximately U′=0.088 and V′=0.543 with a radius less than 0.037.

It will be appreciated by those skilled in the art that changes could be made to the embodiments described above without departing from the broad inventive concept thereof. It is understood, therefore, that the invention disclosed herein is not limited to the particular embodiments disclosed, but it is intended to cover modifications within the spirit and scope of the present invention as defined by the appended claims.

What is claimed is:

1. A method for making a night vision imaging system-compatible LED assembly, the method comprising the steps of:
attaching a light emitting die onto an opaque package;
incorporating near infrared absorbers into an encapsulant; and
molding the encapsulant onto the light emitting die.

2. The method of claim 1, wherein the step of incorporating near infrared absorbers includes near infrared absorbers comprising a metal dithiolene, a rylene, a porphyrin, a phthatocyanine, a naphthalocyanine, or some combination thereof.

3. The method of claim 1, wherein the step of incorporating near infrared absorbers includes near infrared absorbers that substantially absorb energy between 600 and 1200 nanometers of the electromagnetic spectrum.

4. A method for making a night vision imaging system compatible LED assembly, the method comprising the steps of:
attaching a light emitting die onto an opaque package;
incorporating near infrared absorbers into a polymeric lens; and
enclosing the light emitting die with the polymeric lens.

5. The method of claim 4, wherein the step of incorporating near infrared absorbers includes near infrared absorbers comprising a metal dithiolene, a rylene, a porphyrin, a phthalocyanine, a naphthalocyanine, or some combination thereof.

6. The method of claim 4, wherein the step of incorporating near infrared absorbers includes near infrared absorbers that substantially absorb energy between 600 and 1200 nanometers of the electromagnetic spectrum.
